(19) United States
(12) Patent Application Publication
(10) Pub. No.: US 2003/0168731 A1
(43) Pub. Date: Sep. 11, 2003

(54) Thermal interface material and method of fabricating the same

(76) Inventors: James Christopher Matayabas JR., Chandler, AZ (US); Christopher S. Peterson, Gilbert, AZ (US); Paul A. Koning, Chandler, AZ (US)

Correspondence Address: BLAKELY SOKOLOFF TAYLOR & ZAFMAN, 12400 WILSHIRE BOULEVARD, SEVENTH FLOOR, LOS ANGELES, CA, 90025, US

(21) Appl. No.: 10/096,272

(22) Filed: Mar. 11, 2002

(51) Int. Cl. H01L 23/34

(52) U.S. Cl. 257/712

(57) ABSTRACT

A thermal interface material, containing at least one filler material, where the at least one filler material is selected at least in part by particle size, and the method of forming the same, is disclosed.

### BACKGROUND

1. Field

This disclosure relates generally to removal of heat from electronic devices. More specifically, this disclosure relates to thermal interface materials (TIMs), and to methods and apparatus of fabricating a TIM which uses at least one filler, where the filler is selected, at least in part, by particle size distribution.

2. Background Information

There has been rapid development in microelectronic technology recently, and as a result, microelectronic components are becoming smaller, and circuitry within microelectronic components is becoming increasing dense. With a decrease in size of components and an increase of circuit density, heat generation typically increases. Heat dissipation is becoming more critical as the technology develops.

Thermal interface materials (TIMs) are commonly used in microelectronic packages, and may be used, at least in part, to assist in the dissipation of heat from a microelectronic die. Microelectronic packages may comprise at least one die mounted on a substrate or stacked die on a substrate, and may include an additional device in thermal and physical contact with the die, such as, for example, a heat spreader or a case, which may alternatively be referred to as a heat dissipating device. TIMs may be used to fill a gap between a heat generating device and a heat dissipating device, such as an interface between a die and an integrated heat spreader (IHS), for example. TIMs commonly used in the art typically comprise a polymeric base, or matrix, such as a curable polymer, grease, curable gel, elastomeric pad or phase change material and one or more types of thermally conductive fillers. Filler may include, for example, aluminum particles or silver particles. These filler particles typically provide the primary route for heat transfer between one component and another when both are in contact with the TIM, and the variation in size of filler particles as well as the type of material used to fabricate filler particles typically affects thermal performance of the TIM.

Typically, filler in a TIM has a distribution of particle sizes. The distribution that is common in the art of TIMs is heavily right skewed such that the mean particle size is greater than the median particle size and the maximum particle size of filler may be several times larger than the mean particle size in a given TIM. Additionally, the largest filler particles may be present in the lowest or substantially lowest concentrations. This typical filler particle distribution where the largest filler particles are present in the lowest concentration may lead to a TIM having less than optimal thermal performance. Additionally, variations in filler particle sizes may result in a variation in bond line thickness (BLT). BLT is a dimension that is frequently important in the context of microelectronic packages because of its relationship to heat transfer. As is well-known, BLT is the distance from the top of a die to bottom of a case or heat spreader, which may also be referred to as an integrated heat spreader (IHS), in an assembled package. There is typically a need to control the BLT, because the BLT is directly proportional to thermal resistance, which means that for a given TIM higher BLT results in decreases ability to transfer heat. With an increase in the required heat dissipation of a microelectronic package a need exists for a TIM with an improved thermal performance, which also provides control of the BLT.

### BRIEF DESCRIPTION OF THE DRAWINGS

Subject matter is particularly pointed out and distinctly claimed in the concluding portion of the specification. The claimed subject matter, however, both as to organization and method of operation, together with objects, features, and advantages thereof, may best be understood by reference to the following detailed description when read with the accompanying drawings in which:

FIG. 1 is a cross sectional diagram of a microelectronic package in accordance with the claimed subject matter.

FIG. 2 represents two filler particle distributions, including a prior art filler particle distribution, and a filler particle distribution in accordance with the claimed subject matter.

FIG. 3 represents three filler particle distributions in accordance with the claimed subject matter.

### DETAILED DESCRIPTION

In the following detailed description, numerous specific details are set forth in order to provide a thorough understanding of the claimed subject matter. However, it will be understood by those skilled in the art that the claimed subject matter may be practiced without these specific details. In other instances, well-known methods, procedures, and components have not been described in detail so as not to obscure the claimed subject matter.

As is well-known, thermal interface materials (TIMs) may be used in microelectronic packages. TIMs may be used, for example, to assist in the dissipation of heat from a microelectronic die, and may be used to fill a gap between a heat generating device and a heat-dissipating device. A heat-dissipating device may include, for example, a heat spreader or case, heat pipe or a heat sink, although the claimed subject matter is not limited in this respect. For example, a TIM may be used to fill the gap between a die and a heat spreader, although the claimed subject matter is not limited in this respect.

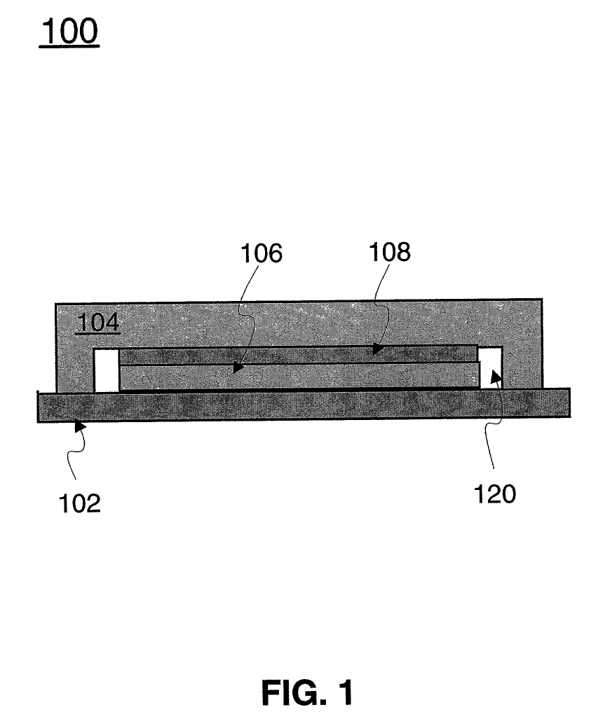

FIG. 1 is a cross sectional diagram of a microelectronic package in accordance with one embodiment of the claimed subject matter. In this embodiment, the cross section of the package 100 comprises a substrate 102, which may also be referred to as a substrate carrier. Typically, the die 106 is electrically and physically attached to the topside of the substrate 102 via a plurality of solder balls or solder bump connections (not shown) although alternative attachment methods exist. Microelectronic package 100 further comprises a heat spreader 104, which typically comprises a mass of conductive material, and may alternatively be referred to as an integrated heat spreader (IHS), a thermal plate, or a case, for example. The heat spreader 104 typically has a cavity 120 formed thereon to at least partially provide a void for the die 106. Typically, when the microelectronic package 100 is fully assembled, the bottom surface of the heat spreader 104 is in thermal contact with the die 106. Thermal contact may be achieved through the use of a TIM 108. TIM 108, in this embodiment, may comprise, for example, a cross-linkable silicone matrix material with aluminum particles as the filler, although the claimed subject matter is not limited in this respect, as will be explained in more detail later. It will, of course, be understood that this is just one example of a microelectronic package that may be used in accordance with one embodiment of the claimed subject matter, and the claimed subject matter is not so limited.

It is important to note that the claimed subject matter is not limited to any particular type or category of TIM, and may be applicable to any TIM that incorporates one or more types, categories or shapes of filler particles. TIMs commonly known in the art typically comprise a base, or matrix material, which may act as a carrier for the filler material. Particular types of matrix materials may include, for example, curable and non-curable polymers like, silicones, epoxies, polyolefins, acrylates, ureathanes or perfluoroethers and solders. In operation, filler particles in a TIM may provide the primary route for conductive heat transfer between one component and another when both are in thermal contact with the TIM. Filler materials may include, for example, aluminum particles, silver, copper, carbon (including diamond or graphite), ceramics, zinc oxide, or any suitable combination thereof, and may additionally comprise any number of shapes, such as, for example, cubic, platelike, rods, flakes, disks, spherical or non-spherical, for example. The claimed subject matter is described primarily in the context of utilization with an integrated circuit flip chip configuration, packaged with a substrate and heat spreader as shown in the accompanying figures. However, it will be understood that the claimed subject matter is not limited to just this particular configuration, and the claimed subject matter is applicable to other types of integrated circuits and other types of packaging, as explained previously.

Typically, a filler material has a distribution of particle sizes. The distribution that is common in the art of TIMs is heavily right skewed such that the mean particle size is greater than the median particle size and the maximum particle size of filler may be several times larger than the mean particle size in a given TIM. Additionally, the largest filler particles may be present in the lowest or substantially lowest concentrations. Experimental results have demonstrated that an increase in the average particle size in a filler, or alternatively where the larger filler particles make up a larger number of the total as compared to well-known TIMs, typically results in an increase in bulk thermal conductivity (BTC). Bulk thermal conductivity, as is well known, is a measure of conductivity, typically expressed in Watts per meter×Kelvin (W/mK). This increase in BTC is due primarily to the generally accepted principle that conductive heat transfer occurs primarily through the filler material of a TIM, and the larger filler particles may be more thermally efficient than smaller filler particles. Therefore, in well-known TIMs, the filler particles that provide the most efficient heat transfer are typically present in the lowest or substantially lowest concentrations. Additionally, fillers with a larger average particle size, when used in a microelectronic package, typically result in a larger bond line thickness (BLT) of a microelectronic package. BLT, as is well known, is a dimension that is frequently important in the context of microelectronic packages, and is the distance from the top of a die to the bottom of a heat spreader or case in an assembled microelectronic package. This dimension may be important, for example, for assembly processes or motherboard layouts. Experiments, in the form of percolation modeling, have demonstrated that for a given quantity of filler, the highest thermal conductivity was achieved when the diameter of the particles in the filler was equal or approximately equal to the BLT. Additionally, this modeling showed that the thermal conductivity decreases as the filler particle size decreases in respect to the BLT, and the thermal sensitivity to particle size variations is the greatest when the filler particle size approaches the BLT. In order to address some of these concerns, and provide a TIM with an improved thermal conductivity while not affecting or not significantly affecting BLT, one embodiment of the claimed subject matter comprises a TIM wherein the median particle size of the filler particles is greater than the mean particle size.

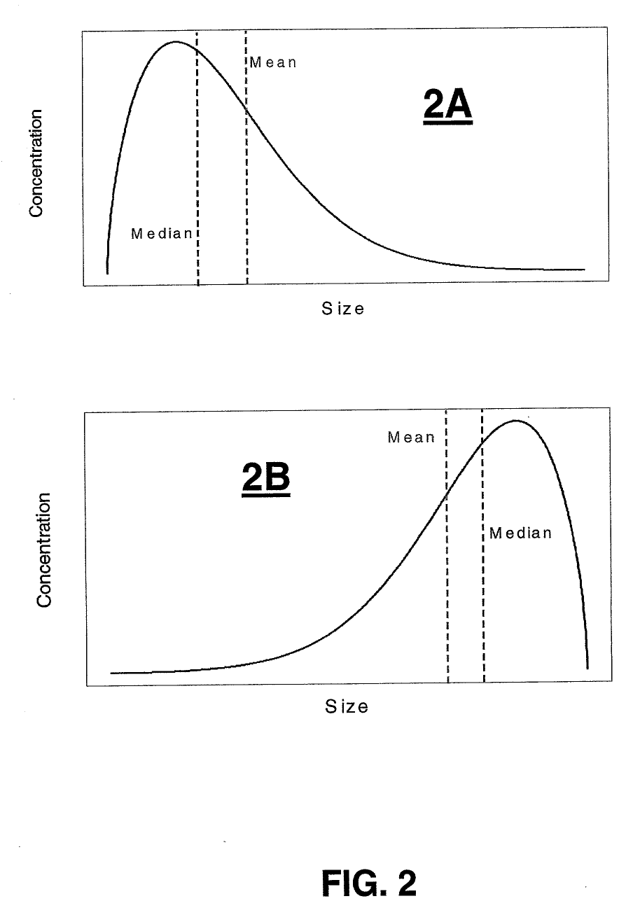

FIGS. 2A and 2B represents two separate distribution curves. Distribution curve FIG. 2A is a distribution curve demonstrating the typical relationship between filler particle size and filler particle concentration common in many TIMs known in the art. As can be seen from FIG. 2A, this is a heavily right-skewed distribution in which the median particle size is less than the mean particle size, meaning, simply put, that the smaller particles are present in greater numbers, and the larger particles are present in lesser numbers. As stated previously, this typical filler particle distribution may result in a TIM that has insufficient thermal performance for some microelectronic packages, and may also result in a high BLT. FIG. 2B is a distribution curve demonstrating one possible filler particle size distribution in accordance with the claimed subject matter. As can be seen from FIG. 2B, the larger filler particles are present in greater numerical quantity, while the smaller particles are present in lesser numerical quantity. As stated previously, this may result in a TIM that has an increased thermal performance as compared to existing TIMs. In this particular embodiment, the TIM may be comprised of a matrix material, and one or more types of filler particles, wherein the median particle size is greater than the mean particle size, meaning, simply put, that the larger particles are present in greater numbers, and the smaller particles are present in lesser numbers. The TIM demonstrated in FIG. 2A may comprise any one of the above described matrix and filler materials, or any combination thereof.

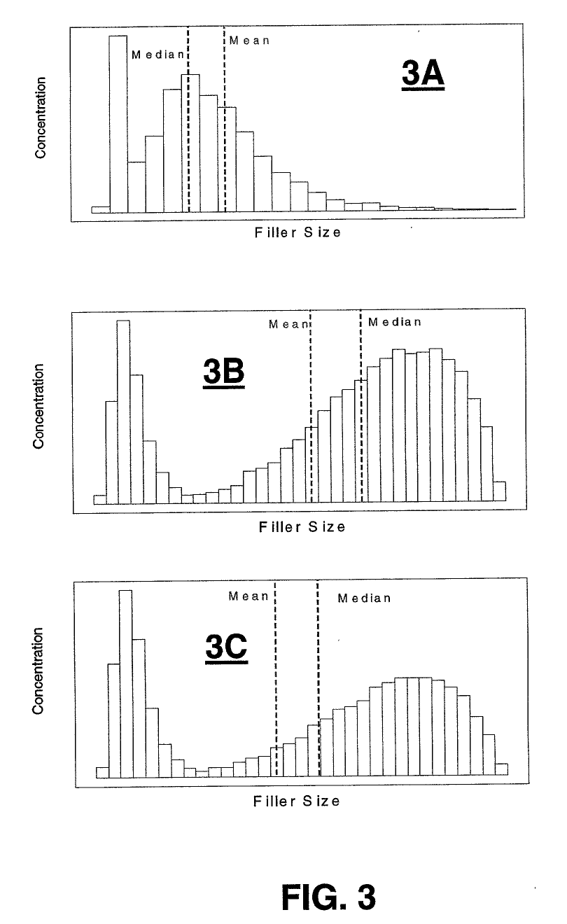

FIG. 3 represents additional distributions where the filler distribution is comprised of a combination of two or more distributions of different particle sizes. Filler distribution 3A represents a typical distribution of filler particle sizes common in many TIMs known in the art where the overall filler distribution is a combination of a distribution of “small” particle sizes and a distribution of larger particle sizes. These “large” and “small” particle size distributions are commonly used in the art and combined in various loadings percentages which result in the distribution of larger particle sizes comprising a greater percentage of the total distribution than the distribution of smaller particle sizes. As can be seen from 3A, the bimodal nature of this distribution reflects the combination of the right skewed distributions of large and small particle sizes, and the overall distribution remains heavily right skewed with the mean particle size larger than the median particle size. 3B is a distribution of overall filler particle sizes demonstrating one possible distribution in accordance with the claimed subject matter. The bimodal appearance of 3B also reflects the combination of the distributions of large and small particle sizes in the same loading percentage of 3A. Simply put, 3B is the combination of a distribution of small particle sizes and a left-skewed distribution of large particle sizes. Furthermore the median particle size of 3B is larger than the mean particle size. Distribution 3C is similar to 3B except that 3C comprises a higher loading percentage of the small particle size distribution than does 3B. However, 3C also represents a combination of a small particle size distribution and a left skewed distribution of large particle sizes such that the median filler size of 3C is larger than the mean particle size.

It is important to note that the above described figures illustrate the claimed distribution where the overall median particle size is greater than the overall mean particle size, regardless of the loading percentages or the number of filler size distributions combined to produce said overall filler distribution.

It can be shown that as the loading percentage of small particle sizes increases, the overall median particle size will no longer be larger than the mean particle size, even when combined with a left-skewed distribution of large particle sizes.

Many methods and techniques may be used to make one or more of the TIMs in accordance with the claimed subject matter. Examples of such techniques may include rigorous particle size separation techniques such as, for example, sieving or air classification. Air classification is a process well known in the art of particle size control, and involves a process whereby particles are separated by particle size by use of forced air. Some of these processes may result in mono dispersed particles, meaning, for example, that all particles separated are within a particular size tolerance. Selective blending may be incorporated to blend these mono dispersed particles, to produce a particular particle size distribution that may be in accordance with one of the previously described embodiments, for example. Alternatively, embodiments of the claimed subject matter may be obtained by combining processes, whereby filler particles are combined in selective processes that may result in narrow filler particle size distributions, and may also result in a relatively large mean. It will, of course, be understood that the claimed subject matter is not limited to any particular method of fabrication, but any such method that results in one or more TIMs that has a combination of large and small particles, wherein the ratio of large versus small, also referred to as the loading, is greater than 50/50 or 1.

As stated previously, the claimed subject matter is not limited to application in just a flip chip microelectronic package. The claimed subject matter may be used in any device or application where a TIM is desirable, and may include an application which may require a TIM for application between a die and heat removal or heat dissipation hardware such as heat sinks, vapor chambers, or fans, for example. Embodiments of the claimed subject matter may comprise any microelectronic package that comprises at least one silicon die, a substrate, and at least one thermal interface material. Microelectronic packages in accordance with the claimed subject matter may include packages with varying form factors, such as, for example, pin grid array, ball grid array, or ball grid array with pinned interposers and wire bonding. It will, of course, be understood that these are just examples of possible embodiments of the claimed subject matter, and the claimed subject matter is not limited in this respect.

While certain features of the claimed subject matter have been illustrated as described herein, many modifications, substitutions, changes, and equivalents will now occur to those skilled in the art. It is, therefore, to be understood that the appended claims are intended to cover all such embodiments and changes as fall within the true spirit of the claimed subject matter.

What is claimed is:

1. A thermal interface material comprising:
at least one matrix material; and
at least one filler comprising particles having a size distribution, wherein a median particle size is greater than or equal to a mean particle size.

2. The thermal interface material of claim 1, wherein said matrix material comprises one of gel, curable polymer, phase change material, elastomeric pad, grease and a mixture thereof.

3. The thermal interface material of claim 1, wherein said matrix material is one of silicone, polyolefin, solder and a mixture thereof.

4. The thermal interface material of claim 1, wherein said filler is one of:
metal fillers such as aluminum, copper, silver, and the like;
ceramic fillers such as zinc oxide, aluminum oxide, aluminum nitride, boron nitride, and silicon nitride, and the like;
carbon fillers such as graphite, carbon fiber, diamond and the like; and mixtures thereof.

5. A method of forming a thermal interface material, the method comprising:
selectively sorting by size at least one set of filler particles;
selecting at least one set of selectively sorted filler particles; and
combining said at least one set with at least one matrix material wherein said particles have a size distribution wherein a median particle size is greater than or equal to a mean particle size.

6. The method of claim 5, wherein selectively sorting comprises air classification.

7. The method of claim 5, wherein said filler particles are sorted by sieving.

8. The method of claim 5, wherein said filler particles are sorted by at least two separate processes.

9. The method of claim 5, wherein at least two sets of sorted particles are selected.

10. A microelectronic package comprising:
a substrate;
at least one microelectronic die attached to said substrate; and
thermal interface material attached to said at least one microelectronic die, wherein the thermal interface material comprises at least one filler, wherein said at least one filler comprises one or more particles, wherein said one or more particles have a size distribution wherein a median particle size is greater than or equal to a mean particle size.

11. The microelectronic package of claim 10, wherein said thermal interface material comprises a matrix material, wherein said matrix material comprises one of gel, curable polymer, phase change material, elastomeric pad, grease and a mixture thereof.

12. The microelectronic package of claim 10, wherein said thermal interface material comprises a matrix material, wherein said matrix material is one of silicone, polyolefin, solder and a mixture thereof.

13. The microelectronic package of claim 10, wherein said filler is one of:
metal fillers such as aluminum, copper, silver, and the like;
ceramic fillers such as zinc oxide, aluminum oxide, aluminum nitride, boron nitride, and silicon nitride, and the like;
carbon fillers such as graphite, carbon fiber, diamond and the like; and mixtures thereof.

14. The microelectronic package of claim 10, wherein said microelectronic die comprises a ball grid array, pin grid array, or land grid array form factor.

15. The microelectronic package of claim 10, and further comprising a socket or interposer.

16. The microelectronic package of claim 10, wherein said microelectronic die comprises two or more dies in stacked, multichip package, or multichip module form factor.

17. An apparatus comprising:
a microelectronic die;
a head spreader; and
a thermal interface material thermally coupling the microelectronic die to the thermal device, and comprising,
a matrix material, and
thermally conductive particles having a size distribution in which an average particle size is smaller than a median particle size.

18. The apparatus of claim 17, wherein said thermal interface material comprises a matrix material, wherein said matrix material comprises one of gel, curable polymer, phase change material, elastomeric pad, grease and a mixture thereof.

19. The apparatus of claim 17, wherein said thermal interface material comprises a matrix material, wherein said matrix material is one of silicone, polyolefin, solder and a mixture thereof.

20. The apparatus of claim 17, wherein said particles are one of:
metal fillers such as aluminum, copper, silver, and the like;
ceramic fillers such as zinc oxide, aluminum oxide, aluminum nitride, boron nitride, and silicon nitride, and the like;
carbon fillers such as graphite, carbon fiber, diamond and the like; and mixtures thereof.

21. The apparatus of claim 17, wherein said microelectronic die comprises a ball grid array, pin grid array, or land grid array form factor.

22. The apparatus of claim 17, and further comprising a socket or interposer.

23. The apparatus of claim 17, wherein said microelectronic die comprises two or more dies in stacked, multichip package, or multichip module form factor.

24. A computer system comprising:
a motherboard;
one or more microelectronic dies attached to the motherboard;
a heat spreader attached to at least one of the microelectronic dies; and
a thermal interface material thermally coupling the heat spreader to the at least one microelectronic dies.

25. The computer system of claim 24, wherein said thermal interface material comprises a matrix material, wherein said matrix material comprises one of gel, curable polymer, phase change material, elastomeric pad, grease and a mixture thereof.

26. The computer system of claim 24, wherein said thermal interface material comprises a matrix material, wherein said matrix material is one of silicone, polyolefin, solder and a mixture thereof.

27. The computer system of claim 24, wherein said thermal interface material comprises one or more particles, wherein said particles are one of:
metal fillers such as aluminum, copper, silver, and the like;
ceramic fillers such as zinc oxide, aluminum oxide, aluminum nitride, boron nitride, and silicon nitride, and the like;
carbon fillers such as graphite, carbon fiber, diamond and the like; and mixtures thereof.

28. The computer system of claim 24, wherein said one or more microelectronic dies comprises a ball grid array, pin grid array, or land grid array form factor.

29. The computer system of claim 24, and further comprising a socket or interposer.

30. The computer system of claim 24, wherein said one or more microelectronic dies comprises two or more dies in stacked, multichip package, or multichip module form factor.

31. A method of manufacturing a microelectronic package, the method comprising:
applying a thermal interface material to at least one of a microelectronic die and a heat spreader; and
coupling the heat spreader to the microelectronic die, with the thermal interface material between, wherein the thermal interface material comprises a least one matrix material, and a quantity of thermally conductive particles whose median size is larger than or equal to their mean size.

32. The method of claim 31, wherein selectively sorting comprises air classification.

33. The method of claim 31, wherein said filler particles are sorted by sieving.

34. The method of claim 31, wherein said filler particles are sorted by at least two separate processes.

35. The method of claim 31, wherein at least two sets of sorted particles are selected.

36. An apparatus comprising:
a heat generating device;
a head spreader; and
a thermal interface material thermally coupling the heat generating device to the heat spreader, and comprising,
a matrix material, and
thermally conductive particles having a size distribution in which an average particle size is smaller than a median particle size.

37. The apparatus of claim 36, wherein said thermal interface material comprises a matrix material, wherein said matrix material comprises one of gel, curable polymer, phase change material, elastomeric pad, grease and a mixture thereof.

38. The apparatus of claim 36, wherein said thermal interface material comprises a matrix material, wherein said matrix material is one of silicone, polyolefin, solder and a mixture thereof.

39. The apparatus of claim 36, wherein said particles are one of:
metal fillers such as aluminum, copper, silver, and the like;
ceramic fillers such as zinc oxide, aluminum oxide, aluminum nitride, boron nitride, and silicon nitride, and the like;
carbon fillers such as graphite, carbon fiber, diamond and the like; and mixtures thereof.

40. The apparatus of claim 36, wherein said microelectronic die comprises a ball grid array, pin grid array, or land grid array form factor.

41. The apparatus of claim 36, and further comprising a socket or interposer.

42. The apparatus of claim 36, wherein said microelectronic die comprises two or more dies in stacked, multichip package, or multichip module form factor.
